(19) United States
(12) Patent Application Publication
(10) Pub. No.: US 2025/0194042 A1
(43) Pub. Date: Jun. 12, 2025

(54) HEAT DISSIPATION APPARATUS AND COMPUTING DEVICE

(71) Applicant: CANAAN CREATIVE CO., LTD., BEIJING (CN)

(72) Inventors: Shaohua ZHANG, BEIJING (CN); Nangeng ZHANG, BEIJING (CN)

(21) Appl. No.: 18/844,816

(22) PCT Filed: Mar. 31, 2023
(86) PCT No.: PCT/CN2023/085698

§ 371 Date: Sep. 6, 2024

(30) Foreign Application Priority Data
Apr. 2, 2022 (CN) 202210357332.X
Apr. 2, 2022 (CN) 202220763638.0

(51) Int. Cl. H05K 7/20; H05K 9/00

(52) U.S. Cl. CPC H05K 7/20172; H05K 7/20145; H05K 7/20409; H05K 9/0041

(57) ABSTRACT

A heat dissipation apparatus and a computing device are provided. The heat dissipation apparatus comprises a shell and at least one heat dissipation fan mounted in the shell; the shell comprises a first panel and side walls arranged in the circumferential direction of the first panel; the at least one heat dissipation fan is arranged on the first panel; the first panel is provided with a first hollow structure corresponding to the at least one heat dissipation fan; the side, away from the first panel, of the at least one heat dissipation fan is configured to face a component to be cooled.

### CROSS REFERENCE TO RELATED APPLICATIONS

This application is a U.S. national stage application under 35 U.S.C. § 371 of International Application No. PCT/CN2023/085698, filed internationally on Mar. 31, 2023, which claims priority to Chinese Patent Application No. 202210357332.X, filed with the China Patent Office on Apr. 2, 2022 and titled “HEAT DISSIPATION APPARATUS AND COMPUTING DEVICE”, which are incorporated herein by reference in their entirety.

International Application No. PCT/CN2023/085698 also claims priority to Chinese Patent Application No. 202220763638.0, filed with the China Patent Office on Apr. 2, 2022 and titled “HEAT DISSIPATION APPARATUS AND COMPUTING DEVICE”, which is incorporated herein by reference in its entirety.

### TECHNICAL FIELD

The present disclosure relates to the field of data computing technology, and, in particular, to a heat dissipation apparatus and a computing device.

### BACKGROUND

The rapid development of modern industrial technology has promoted the pace of development of various components of processing devices towards automation and intelligence. A computing device is an electronic device for high-speed computing, for example, for running a particular algorithm and communicating with a remote server to obtain a corresponding electronic device. The computing device includes a plurality of heat generation components, and a too high temperature of the heat generation components will affect the computing efficiency of the computing device. Therefore, good heat dissipation needs to be performed for the heat generation components.

### SUMMARY

Embodiments of the present disclosure provide a heat dissipation apparatus and a computing device to solve or alleviate one or more technical problems in the existing technology.

As one aspect of the embodiments of the present disclosure, an embodiment of the present disclosure provides a heat dissipation apparatus, including a shell and at least one heat dissipation fan mounted in the shell, wherein the shell includes a first panel and side walls disposed along a circumferential direction of the first panel, the at least one heat dissipation fan is disposed on the first panel, the first panel is provided with a first hollowed-out structure corresponding to the at least one heat dissipation fan, and a side of the at least one heat dissipation fan away from the first panel is configured to face towards a component to be cooled.

In some possible implementations, the heat dissipation fan includes at least two heat dissipation fans side by side in a plurality of columns in a first direction, wherein the first direction is a direction parallel to an air passage direction of the heat dissipation fans.

In some possible implementations, the heat dissipation fan includes at least two heat dissipation fans arrayed in a plurality of rows along a second direction, wherein the second direction is a direction perpendicular to an air passage direction of the heat dissipation fans.

In some possible implementations, the heat dissipation fan includes at least three heat dissipation fans side by side in a plurality of columns in a first direction and arrayed in a plurality of rows in a second direction, wherein the first direction is a direction parallel to an air passage direction of the heat dissipation fans, and the second direction is a direction perpendicular to the air passage direction of the heat dissipation fans.

In some possible implementations, the first hollowed-out structure corresponds to a fin of the heat dissipation fan, and the first hollowed-out structure includes a plurality of first ventilation holes.

In some possible implementations, the first panel is provided with a mounting hole, and the heat dissipation fan close to the first panel is fixed in the mounting hole through a screw.

In some possible implementations, two adjacent heat dissipation fans in the first direction are fixedly connected through a screw.

In some possible implementations, the heat dissipation fan is provided with a fixing hole close to an edge of the heat dissipation fan.

In some possible implementations, the heat dissipation fans are provided with fixing holes, and the first panel is provided with mounting holes matching the fixing holes, and fixing screws sequentially pass through the mounting holes and the fixing holes of at least two columns of the heat dissipation fans arrayed along the first direction to fix the at least two columns of heat dissipation fans, wherein the first direction is a direction parallel to an air passage direction of the heat dissipation fans.

As one aspect of the embodiments of the present disclosure, an embodiment of the present disclosure provides a computing device, comprising a heat generation module and the heat dissipation apparatus of any embodiment of the present disclosure, wherein the heat generation module is located in the shell of the heat dissipation apparatus, and the heat dissipation fan(s) in the heat dissipation apparatus is located on at least a side of the heat generation module.

In some possible implementations, the heat dissipation fan(s) in the heat dissipation apparatus is located on a first side of the heat generation module, and a side of the heat dissipation fan(s) in the heat dissipation apparatus away from the first panel faces towards the heat generation module.

In some possible implementations, the side walls of the heat dissipation apparatus are an integrally molded structure.

In some possible implementations, the computing device further includes a second panel located on a second side of the heat generation module, mounted on the side walls, and provided with a plurality of heat dissipation grids, and the second side is opposite to the first side.

In some possible implementations, the heat dissipation grids have a size in a range from 4.5 mm to 5.5 mm.

In some possible implementations, a distance between the heat dissipation fan(s) in the heat dissipation apparatus and the heat generation module in a first direction ranges from 20 mm to 30 mm, and the first direction is a direction parallel to an air passage direction of the heat dissipation fan(s).

In some possible implementations, a distance between the second panel and the heat generation module in a first direction ranges from 0 to 5 mm, and the first direction is a direction parallel to an air passage direction of the heat dissipation fan(s).

In some possible implementations, the heat generation module includes a plurality of computing power board assemblies arranged in parallel, a limiting body is disposed on a side of the second panel towards the heat generation module, and the limiting body abuts against at least one of the computing power board assemblies.

In some possible implementations, the limiting body protrudes towards the heat generation module.

In some possible implementations, the heat dissipation apparatus includes two heat dissipation apparatuses located on two opposite sides of the heat generation module along a first direction respectively, and the first direction is a direction parallel to an air passage direction of the heat dissipation fans in the heat dissipation apparatuses.

In some possible implementations, the heat generation module includes a plurality of computing power board assemblies arranged in parallel, each disposed in the shell along a first direction, and the first direction is a direction parallel to an air passage direction of the heat dissipation fan(s) in the heat dissipation apparatus(es).

In some possible implementations, a limiting strip is mounted on an inner side of a bottom wall and/or top wall of the side walls, the limiting strip is disposed along an arrangement direction of the computing power board assemblies, the limiting strip is located between the heat dissipation apparatus(es) and the computing power board assemblies, and each of the computing power board assemblies abuts against the limiting strip.

According to the technical solutions of the embodiments of the present disclosure, the shell can protect the heat dissipation fan, so that external dust entering an interior of the heat dissipation fan can be reduced, and external dust entering an interior of the computing device along with an airflow can be reduced, ensuring the cleanliness of internal components of the computing device, and facilitating the improvement to the computing efficiency of the computing device.

The above summary is only for the purpose of the specification, and is not intended to make limitations in any way. In addition to the aspects, implementations, and features described above, further aspects, implementations, and features of the present application will be easily understood by referring to the drawings and the following detailed description.

### BRIEF DESCRIPTION OF THE DRAWINGS

In the drawings, unless otherwise specified, the same reference numerals throughout the plurality of drawings represent the same or similar components or elements. These drawings are not necessarily drawn to scale. It should be understood that these drawings only depict some implementations disclosed in the present application and should not be regarded as limitations on the scope of the present application.

FIG. 1 is a schematic structural view of a computing device in the related technology.

FIG. 2 is a schematic structural view of a heat dissipation apparatus in an embodiment of the present disclosure.

FIG. 3 is an exploded schematic structural view of the heat dissipation apparatus shown in FIG. 2.

FIG. 4 is a semi-perspective view of the heat dissipation apparatus in an embodiment of the present disclosure after being mounted in a computing device.

FIG. 5 is a schematic structural view of a computing device in an embodiment of the present disclosure.

FIG. 6 is a schematic view of the computing device shown in FIG. 5 in another direction.

FIG. 7 is a partially exploded schematic structural view of the computing device in an embodiment of the present disclosure.

FIG. 8 is a schematic view of an internal structure of the computing device in an embodiment of the present disclosure.

FIG. 9 is a schematic view of a shell in an embodiment of the present disclosure in which a heat generation module is mounted.

FIG. 10 is a schematic view of a limiting strip in FIG. 9.

### REFERENCE NUMERALS

10. heat dissipation apparatus: 11. shell: 111. side wall: 112. first panel: 1121. first hollowed-out structure: 1122. mounting hole: 12. heat dissipation fan: 22. second panel: 221. heat dissipation grid: 23. limiting strip: 231. fixing part: 232. limiting part: 31. heat generation module: 311. computing power board assembly: 50. fixing screw.

### DETAILED DESCRIPTION

Only some exemplary embodiments are briefly described below. Just as those skilled in the art may appreciate, the described embodiments may be modified in various ways without departing from the spirit or scope of the present application. Therefore, the drawings and description are considered to be exemplary in nature, not limitative.

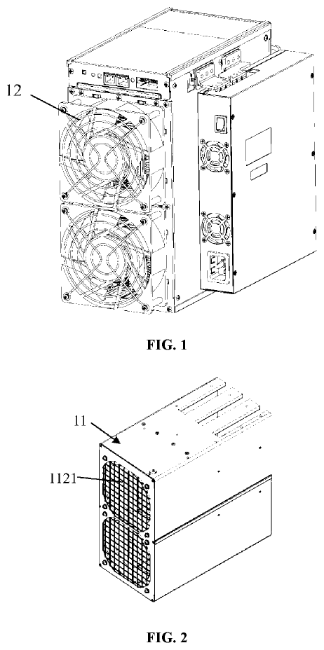

FIG. 1 is a schematic structural view of a computing device in the related technology. As shown in FIG. 1, in the related technology, a heat dissipation fan 12 is disposed outside of a computing device. The heat dissipation fan 12 is uncovered, and external dust will easily contaminate the heat dissipation fan 12, which reduces the heat dissipation effect of the heat dissipation fan 12. Furthermore, external dust easily enters the computing device along with an airflow of the heat dissipation fan 12, and contaminates components inside the computing device, leading to a reduced heat dissipation effect on the components inside the computing device, and affecting the computing efficiency.

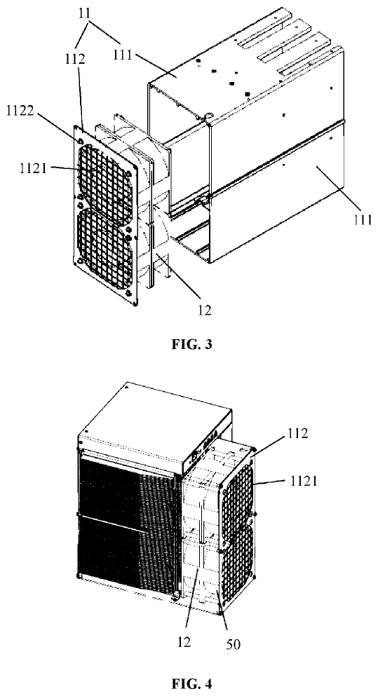

FIG. 2 is a schematic structural view of a heat dissipation apparatus in an embodiment of the present disclosure, FIG. 3 is an exploded schematic structural view of the heat dissipation apparatus shown in FIG. 2, and FIG. 4 is a semi-perspective view of the heat dissipation apparatus in an embodiment of the present disclosure after being mounted in a computing device. As shown in FIG. 2 and FIG. 3, a heat dissipation apparatus can include a shell 11 and at least one heat dissipation fan 12 mounted in the shell 11. The shell 11 can include a first panel 112 and side walls 111 that can be disposed along a circumferential direction of the first panel 112. The at least one heat dissipation fan 12 is disposed on the first panel 112, so that the first panel 112 and the side walls 111 together enclose the at least one heat dissipation fan 12. The first panel 112 is provided with a first hollowed-out structure 1121 corresponding to the at least one heat dissipation fan 12, and the heat dissipation fan 12 can exchange air flow with the external through the first hollowed-out structure 1121. As shown in FIG. 4, a side of the at least one heat dissipation fan 12 away from the first panel 112 is configured to face towards a component to be cooled, so as to perform heat dissipation for the component to be cooled.

In the heat dissipation apparatus of the embodiment of the present disclosure, the shell 11 can wrap around the heat dissipation fan 12 to protect the heat dissipation fan 12, so that external dust entering an interior of the heat dissipation fan 12 can be reduced, and an outside worker can be prevented from touching the heat dissipation fan 12 to provide safety: by disposing the first hollowed-out structure 1121, gas exchange is achieved between the heat dissipation fan 12 and the external, which in turn achieves heat dissipation for the component to be cooled, and the first hollowed-out structure 1121 can form a certain barrier to external dust, and reduce external dust that enters an interior of the computing device along with an airflow, ensuring the cleanliness of internal components of the computing device, and facilitating the improvement to the computing efficiency of the computing device: the side of the at least one heat dissipation fan 12 away from the first panel 112 has no blocking wall, and therefore, the heat dissipation fan 12 can sufficiently perform heat dissipation for the component to be cooled, which will not affect the heat dissipation effect.

Such a heat dissipation apparatus not only achieves the heat dissipation for the component to be cooled, but also can reduce external dust entering the interior of the heat dissipation fan 12, and reduce external dust entering the interior of the computing device along with the airflow, ensuring the cleanliness of the internal components of the computing device, and facilitating the improvement to the computing efficiency of the computing device.

It should be noted that a material and thickness of the shell 11 can be set according to needs. Exemplarily, the shell 11 can be made of metal, so as to improve structural stability of the heat dissipation apparatus.

In an implementation, as shown in FIG. 3, the number of the heat dissipation fan 12 can include at least two heat dissipation fans 12 side by side in a plurality of columns in a first direction, and the first direction can be a direction parallel to an air passage direction of the heat dissipation fans 12. The air passages of two adjacent fans along the first direction are in communication. For example, in a direction along the first panel towards a component to be cooled, an air outlet side of a preceding fan of the two adjacent fans is in communication with an air inlet side of a subsequent fan. Such a disposing manner can increase a gas flow rate in the air passages, thereby increasing the gas exchange capacity between the air passages and the external, and improving the heat dissipation effect. Exemplarily, a plurality of heat dissipation fans can be disposed in a same column, and the plurality of heat dissipation fans 12 located in the same column can be arrayed along a second direction, and the second direction can be a direction perpendicular to the air passage direction of the heat dissipation fans. Disposing the plurality of heat dissipation fans 12 in the same column can increase a heat dissipation area and further improve the heat dissipation effect.

I In an implementation, the heat dissipation fan can include at least two heat dissipation fans arrayed in a plurality of rows along a second direction, and the second direction is a direction perpendicular to an air passage direction of the heat dissipation fans. In such a disposing manner, the at least two heat dissipation fans are disposed on a plane parallel to the first panel 112, which can increase a heat dissipation area and further improve the heat dissipation effect.

In an implementation, the heat dissipation fan includes at least three heat dissipation fans side by side in a plurality of columns in a first direction and arrayed in a plurality of rows in a second direction, and the first direction is a direction parallel to an air passage direction of the heat dissipation fans, and the second direction is a direction perpendicular to the air passage direction of the heat dissipation fans. Such a disposing manner can increase a gas flow rate in the air passages, thereby increasing the gas exchange capacity between the air passages and the external, and improving the heat dissipation effect. Furthermore, the at least two heat dissipation fans are disposed on a plane parallel to the first panel, which can increase a heat dissipation area, and further improve the heat dissipation effect.

In one embodiment, the heat dissipation fan 12 can include four heat dissipation fans side by side in two columns in a first direction, in which two heat dissipation fans 12 can be disposed in one and the same column. It should be noted that, in a specific implementation process, the number of columns of the heat dissipation fans 12 in the first direction and the number of the heat dissipation fans 12 in each column can be set according to needs.

In an implementation, the heat dissipation fan 12 includes a plurality of heat dissipation fans arrayed along a second direction, and the second direction can be a direction perpendicular to an air passage direction of the heat dissipation fans 12, that is to say, the plurality of heat dissipation fans 12 are disposed in one column. In such a manner, the heat dissipation area is increased, and only one column of the heat dissipation fans 12 is disposed between the external and a component to be cooled, so that a length of an air passage is only a thickness of the heat dissipation fan 12, greatly reducing the length of the air passage, improving a rate of heat exchange of gas between the external and the component to be cooled, and further improving the heat dissipation effect.

In an implementation, as shown in FIG. 2 and FIG. 3, the first hollowed-out structure 1121 corresponds to a fin of the heat dissipation fan 12. The first hollowed-out structure 1121 includes a plurality of first ventilation holes. With the first hollowed-out structure 1121 in such a structure, gas can circulate through the first ventilation holes, and connecting parts between adjacent first ventilation holes can play a role in blocking dust and reducing dust that enters the air passage of the heat dissipation fan 12: Exemplarily, the first hollowed-out structure 1121 is disposed in such a manner as to correspond to a working area of the fin of the heat dissipation fan 12, so that the fin of the heat dissipation fan 12, in a working process, can perform gas exchange with the external to the greatest extent, expand an airflow circulation area, and further improve the heat dissipation effect.

In an implementation, the heat dissipation fan 12 is provided with a fixing hole that can be close to an edge of the heat dissipation fan. For example, the heat dissipation fan 12 can include four fixing holes that can be located at four corner edges of the heat dissipation fan 12, respectively. As such, it can be convenient to mount and fix the heat dissipation fan 12 through the fixing holes.

In an implementation, as shown in FIG. 3 and FIG. 4, the first panel 112 is provided with a mounting hole 1122, and the heat dissipation fan 12 close to the first panel 112 can be fixed in the mounting hole 1122 through a screw. In such a mounting manner, the structure is simple and easy mounting is made. For example, a screw can be employed to fixedly connect the fixing hole with the mounting hole 1122, thereby fixing the heat dissipation fan 12.

In an implementation, two adjacent heat dissipation fans 12 in the first direction can be fixedly connected through a screw.

In an implementation, the heat dissipation fans 12 are provided with fixing holes that can be close to edges of the heat dissipation fans. The first panel 112 is provided with mounting holes 1122 matching the fixing holes, and fixing screws 50 sequentially pass through the mounting holes 1122 and the fixing holes of at least two columns of the heat dissipation fans 12 arrayed along the first direction to fix the at least two columns of the heat dissipation fans 12, as shown in FIG. 4. The first direction is a direction parallel to an air passage direction of the heat dissipation fans 12. The first panel 112 can be removably connected to the shell 11, and by mounting the heat dissipation fans 12 on the first panel 112, it is convenient to remove and replace the heat dissipation fans 12.

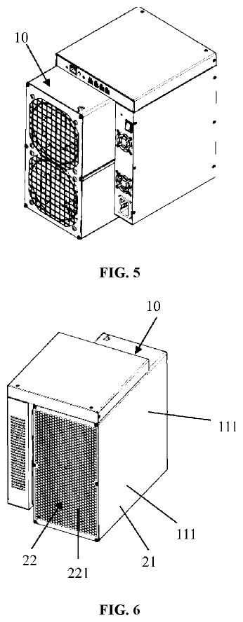

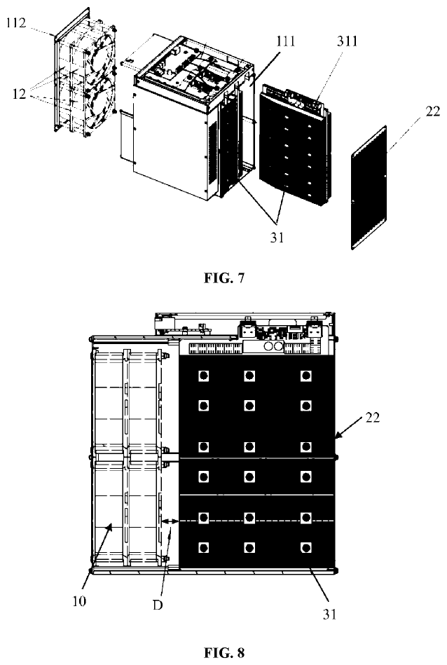

FIG. 5 is a schematic structural view of a computing device in an embodiment of the present disclosure, FIG. 6 is a schematic view of the computing device shown in FIG. 5 in another direction, FIG. 7 is a partially exploded schematic structural view of the computing device in an embodiment of the present disclosure, and FIG. 8 is a schematic view of an internal structure of the computing device in an embodiment of the present disclosure. In an implementation, as shown in FIG. 5, FIG. 6, FIG. 7 and FIG. 8, the computing device can include a heat generation module 31, and can further include the heat dissipation apparatus 10 in any embodiment of the present disclosure. The heat generation module 31 can be located in the shell 11 of the heat dissipation apparatus, the heat dissipation fan(s) 12 in the heat dissipation apparatus 10 is located on a first side of the heat generation module 31, and a side of the heat dissipation fan(s) 12 in the heat dissipation apparatus 10 away from the first panel 112 faces towards the heat generation module 31. It can be understood that the heat generation module 31 is a module to be cooled.

In the computing device in the embodiment of the present disclosure, the heat dissipation apparatus 10 provided in the embodiment of the present disclosure is employed to perform heat dissipation for the heat generation module 31, which can reduce external dust entering an interior of the computing device through the heat dissipation apparatus 10, ensuring the cleanliness of internal components of the computing device, and facilitating the improvement to the computing efficiency of the computing device.

In an implementation, as shown in FIG. 6 and FIG. 7, the side walls 111 of the heat dissipation apparatus 10 can be an integrally molded structure. For example, the side walls 111 can be molded at one time through a stamping process. Exemplarily, the side walls 111 can extend towards a direction of the heat generation module 31 and enclose the heat generation module 31, so that the heat generation module 31 is located in the shell 11, as shown in FIG. 3 and FIG. 6. Such a shell can improve the structural strength and stability of the computing device, and improve the assembly efficiency.

In an implementation, as shown in FIG. 6 and FIG. 7, the computing device can further include a second panel 22 that can be located on a second side of the heat generation module 31, and the second side of the heat generation module 31 is disposed opposite to the first side of the heat generation module 31, that is to say, the second panel 22 can be located on a side of the heat generation module 31 away from the heat dissipation fan(s) 12. The second panel 22 is mounted on the side walls 111, and the second panel 22 is provided with a plurality of heat dissipation grids 221. The heat dissipation grids 221 have a size that can be set according to actual needs.

In such a disposing manner, the first panel 112, the heat dissipation fan(s) 12, the heat generation module 31 inside the shell 11, and the second panel 22 can form an airflow circulation channel, external cold air can enter an interior of the shell 11 through the first panel 112 and the heat dissipation fan(s) 12 to perform heat dissipation for the heat generation module 31, and air that absorbs heat can be discharged to the external through the second panel 22, so as to implement a heat dissipation process and achieve a good heat dissipation effect.

The second panel 22 is mounted on the sidewalls 111, so that the second panel 22 can play a role in supporting the shell 11 and provide the structural strength of the shell 11. Exemplarily, a material of the second panel 22 can be metal.

It can be understood that the heat generation module 31 can be an electrical component, and the electrical component is susceptible to interference from an external signal. By disposing the second panel 22, part of external interference signals can be shielded, and the working stability of the heat generation module 31 can be improved.

Exemplarily, the heat dissipation grids 221 have a size in a range from 4.5 mm to 5.5 mm (inclusive of endpoint values), that is to say, the size of the heat dissipation grids 221 can be any value between 4.5 mm and 5.5 mm. For example, the size of the heat dissipation grids 221 can be 4.5 mm, 5 mm or 5.5 mm. The heat dissipation grids 221 of such a size can not only well ensure the gas circulation, but also ensure that the second panel 22 has a good signal shielding effect. The heat dissipation grids 221 can have a regular or irregular shape, such as a circle or a hexagon. A specific shape of the heat dissipation grids is not defined here, and the specific shape of the heat dissipation grids can be set according to needs.

In an implementation, as shown in FIG. 8, a distance D between the heat dissipation fan(s) 12 in the heat dissipation apparatus 10 and the heat generation module 31 in a first direction can range from 20 mm to 30 mm (inclusive of endpoint values), and the first direction is a direction parallel to an air passage direction of the heat dissipation fan 12. The distance D between the heat dissipation fan(s) 12 and the heat generation module 31 in the first direction can be any value between 20 mm and 30 mm, for example, 20 mm, 25 mm or 30 mm. By setting the distance D between the heat dissipation fan(s) 12 and the heat generation module 31, an airflow can be buffered, which facilitates the heat exchange of cold and hot airflows, and further improve the heat dissipation efficiency: at the same time, the heat generation module 31 also can be avoided from being in direct contact with the heat dissipation fan(s) 12, which prolongs the service life of the heat dissipation fan(s) 12.

In an implementation, as shown in FIG. 8, a distance between the second panel 22 and the heat generation module 31 in a first direction ranges from 0 to 5 mm (inclusive of endpoint values). Exemplarily, the distance between the second panel 22 and the heat generation module 31 in the first direction can be any value between 0 and 5 mm, such as 0, 2 mm or 5 mm. By defining the distance between the second panel 22 and the heat generation module 31 to be 0 to 5 mm, the second panel 22 can properly limit the heat generation module 31 in the first direction, and no other limiting components will be needed.

In an implementation, as shown in FIG. 7, the heat generation module 31 includes a plurality of computing power board assemblies 311 arranged in parallel, a limiting body can be disposed on a side of the second panel 22 towards the heat generation module 31, and the limiting body abuts against at least one of the computing power board assemblies 311. Exemplarily, the computer board assembly 311 can be a hardware structure in which a plurality of computing functional chips is disposed on a circuit board. It can be understood that a computing power board assembly 311 can be stuck in the shell through a slideway, and a phenomenon that the computing power board assembly 311 slides in the slideway may occur in a transportation process. By disposing the limiting body abutting against each computing power board assembly 311 on the side of the second panel 22 towards the heat generation module 31, the computing power board assembly 311 can be better limited, preventing the computing power board assembly 311 from slipping in a transportation process.

It should be noted that a specific shape and position of the limiting body can be set according to needs, as long as it can abut against a computing power board assembly 311 to limit the same. The number of the limiting bodies can match the number of the computing power board assemblies 311, so that each limiting body can limit a corresponding computing power board assembly 311. There can be one or more limiting bodies, in which one limiting body can abut against at least two computing power board assemblies 311. Exemplarily, the limiting body can protrude towards a direction of the heat generation module 31, so as to abut against the heat generation module 31 to limit the same. Exemplarily, a material of the limiting body can include an elastic material. For example, the limiting body is made of an elastic material. Exemplarily, an end of the limiting body can be provided with an elastic component that can abut against each computing power board assembly. The elastic component or the elastic material can avoid the assembly problem caused by a mounting error.

In one embodiment, the limiting body can be located at an upper portion, a middle portion or a lower portion of the second panel 22 along a height direction of a computing power board assembly 311, as long as the limiting body can abut against the computing power board assembly 311.

The number of the computing power board assemblies 311 shown in FIG. 7 is three, and in actual implementation, the number of the computing power board assemblies 311 can be set according to needs.

In an implementation, as shown in FIG. 7, each of the power calculation plate assemblies 311 is disposed in the shell 11 along a first direction, and the first direction is a direction parallel to an air passage direction of the heat dissipation fans 12. Such a disposing manner can increase a contact area between the computing power board assemblies 311 and the air passages of the heat dissipation fans 12, which in turn increases a heat dissipation area for the computing power board assemblies 311 and improve the heat dissipation efficiency.

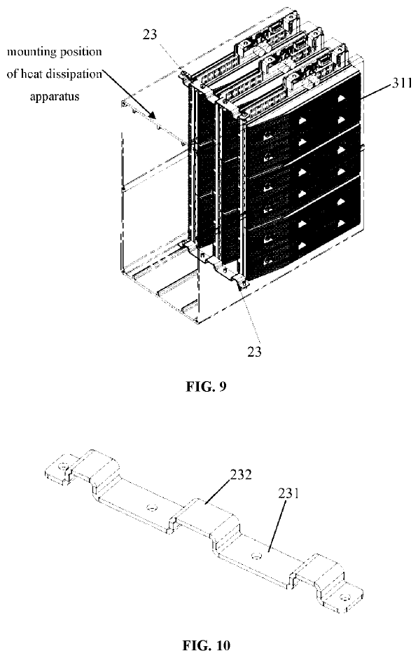

FIG. 9 is a schematic view of a shell in an embodiment of the present disclosure in which a heat generation module is mounted, and FIG. 10 is a schematic view of a limiting strip in FIG. 9. In an implementation, a limiting strip 23 is mounted on an inner side of a bottom wall and/or top wall of the side walls 111, and the limiting strip 23 can be disposed along an arrangement direction of the computing power board assemblies 311. The limiting strip 23 is located between the heat dissipation apparatus and the computing power board assemblies 311, and each of the computing power board assemblies 311 abuts against the limiting strip 23. With such a structure, the limiting strip 23 can limit an inner side of the computing power board assemblies 311, and prevent the computing power board assembly 311 from slipping in a transportation process.

Exemplarily, the limiting strip 23 can be mounted on one of the bottom wall and the top wall of the side walls 111, or the limiting strip 23 can be mounted on both the bottom wall and the top wall of the side walls 111.

As shown in FIG. 9 and FIG. 10, the limiting strip 23 can include a fixing part 231 and a limiting part 232, and the limiting strip 23 is fixed on the bottom wall and/or the top wall through the fixing part 231. Exemplarily, the limiting part 232 can protrude from the fixing part 231, and the limiting part 232 is used to be abutted against by a computing power board assembly 311.

In the embodiment shown in FIG. 7, heat dissipation fans 12 are disposed on a side of the side walls 111. By setting a mounting direction of the heat dissipation fans 12, the heat dissipation fans 12 can be enabled to blow air towards the heat generation module to dissipate heat, or the heat dissipation fans 12 can be enabled to draw away heat generated by the heat generation module to dissipate heat.

In an implementation, the heat dissipation apparatus 10 can include two heat dissipation apparatuses 10 located on two opposite sides of the heat generation module 31 along a first direction respectively, and the first direction is a direction parallel to an air passage direction of the heat dissipation fans 12 in the heat dissipation apparatuses. Exemplarily, the side walls of the two heat dissipation apparatuses can be in an integral structure, that is to say, the two heat dissipation apparatuses share the same side walls 111. In the two heat dissipation apparatuses, an air outlet side of a first heat dissipation apparatus is in communication with an air inlet side of a second heat dissipation apparatus, so that one of the heat dissipation apparatuses 10 can blow air towards the heat generation module 31, and the other can draw air outwards from the heat generation module 31, so that air passages of the two heat dissipation apparatuses 20 are communicated in series, which can further improve the heat dissipation efficiency and enhance the heat dissipation effect.

It should be noted that a mounting structure of the first heat dissipation apparatus and the second heat dissipation apparatus is not limited to the above description, and it can also be considered that an air inlet side of the first heat dissipation apparatus is in communication with an air outlet side of the second heat dissipation apparatus, or the air inlet side of the first heat dissipation apparatus is in communication with the air inlet side of the second heat dissipation apparatus, or the air outlet side of the first heat dissipation apparatus is in communication with the air outlet side of the second heat dissipation apparatus.

In the description of this specification, it should be understood that the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like indicate orientations or positional relationships based on the orientations or positional relationships shown in the drawings, and are only for the convenience of describing the present application and simplifying the description, and do not indicate or imply that a device or element as mentioned must have a particular orientation, or be constructed and operated in a particular orientation, and therefore should not be understood as a limitation on the present application.

In addition, the terms “first” and “second” are used for descriptive purposes only and should not be understood as indicating or implying relative importance or implicitly stating the number of technical features as indicated. Accordingly, a feature defined by “first” or “second” may explicitly or implicitly include one or more of the features. In the description of the present application, the meaning of “plurality” is two or more than two, unless otherwise clearly and specifically defined.

In the present application, unless otherwise clearly specified and defined, the terms “mount”, “connect with”, “connect”, “fix” and the like should be understood in a broad sense. For example, it is possible to be a fixed connection, a detachable connection, or an integration: it is possible to be a mechanical connection, an electrical connection, or a communication: it is possible to be a direct connection, or an indirect connection through an intermediate medium, or an internal communication between two elements or an interaction relationship between two elements. For those skilled in the art, the specific meanings of the above terms in the present application can be understood as a specific case may be.

In the present application, unless otherwise clearly specified and defined, a first feature being “on” or “under” a second feature may include a case that the first and second features are in direct contact, or a case that the first and second features are not in direct contact but are in contact through an additional feature between them. Moreover, a first feature being “on”, “above” and “over” a second feature includes a case that the first feature is directly above and obliquely above the second feature, or simply represents that the first feature is higher in level than the second feature. A first feature being “under”, “below” and “beneath” a second feature includes a case that the first feature is directly below and obliquely below the second feature, or simply represents that the first feature is lower in level than the second feature.

The disclosure above provides many different embodiments or instances to achieve the different structures of the present application. In order to simplify the disclosure of the present application, the parts and settings of particular instances are described above. Certainly, they are only examples, and their purpose is not to limit the present application. In addition, in the present application, reference numerals and/or reference letters can be repeated in different instances, and such repetition is for the purpose of simplification and clarity, which itself does not indicate the relationships between the various implementations and/or settings discussed.

Described above are only specific implementations of the present application, but the scope of protection of the present application is not limited thereto. Any technicians familiar with this technical field can readily envisage various changes or substitutions within the technical scope disclosed in the present application, all of which should be included in the scope of protection of the present application. Therefore, the scope of protection of the present application should be based on the scope of protection of the attached claims.

1. A heat dissipation apparatus, comprising a shell and at least one heat dissipation fan mounted in the shell, wherein the shell comprises a first panel and side walls disposed along a circumferential direction of the first panel, the at least one heat dissipation fan is disposed on the first panel, the first panel is provided with a first hollowed-out structure corresponding to the at least one heat dissipation fan, and a side of the at least one heat dissipation fan away from the first panel is configured to face towards a component to be cooled.

2. The heat dissipation apparatus of claim 1, wherein the heat dissipation fan comprises at least two heat dissipation fans side by side in a plurality of columns in a first direction, and the first direction is a direction parallel to an air passage direction of the heat dissipation fans.

3. The heat dissipation apparatus of claim 1, wherein the heat dissipation fan comprises at least two heat dissipation fans arrayed in a plurality of rows along a second direction, and the second direction is a direction perpendicular to an air passage direction of the heat dissipation fans.

4. The heat dissipation apparatus of claim 1, wherein the heat dissipation fan comprises at least three heat dissipation fans, with the at least two heat dissipation fans side by side in a plurality of columns in a first direction and arrayed in a plurality of rows in a second direction, the first direction is a direction parallel to an air passage direction of the heat dissipation fans, and the second direction is a direction perpendicular to the air passage direction of the heat dissipation fans.

5. The heat dissipation apparatus of claim 1, wherein the first hollowed-out structure corresponds to a fin of the heat dissipation fan, and the first hollowed-out structure comprises a plurality of first ventilation holes.

6. The heat dissipation apparatus of claim 1, wherein the first panel is provided with a mounting hole, and the heat dissipation fan close to the first panel is fixed in the mounting hole through a screw.

7. The heat dissipation apparatus of claim 2, wherein two adjacent heat dissipation fans in the first direction are fixedly connected through a screw.

8. The heat dissipation apparatus of claim 1, wherein the heat dissipation fan is provided with a fixing hole close to an edge of the heat dissipation fan.

9. The heat dissipation apparatus of claim 2, wherein the heat dissipation fans are provided with fixing holes, and the first panel is provided with mounting holes matching the fixing holes, and fixing screws sequentially pass through the mounting holes and the fixing holes of at least two columns of the heat dissipation fans arrayed along the first direction to fix the at least two columns of heat dissipation fans, and the first direction is a direction parallel to an air passage direction of the heat dissipation fans.

10. A computing device, comprising a heat generation module and a heat dissipation apparatus, the heat dissipation apparatus comprises a shell and at least one heat dissipation fan mounted in the shell, wherein the shell comprises a first panel and side walls disposed along a circumferential direction of the first panel, the at least one heat dissipation fan is disposed on the first panel, the first panel is provided with a first hollowed-out structure corresponding to the at least one heat dissipation fan, and a side of the at least one heat dissipation fan away from the first panel is configured to face towards a component to be cooled, and the heat generation module is located in the shell of the heat dissipation apparatus, and the heat dissipation fan(s) in the heat dissipation apparatus is located on at least a side of the heat generation module.

11. The computing device of claim 10, wherein the heat dissipation fan(s) in the heat dissipation apparatus is located on a first side of the heat generation module, and a side of the heat dissipation fan(s) in the heat dissipation apparatus away from the first panel faces towards the heat generation module.

12. The computing device of claim 10, wherein the side walls of the heat dissipation apparatus are an integrally molded structure.

13. The computing device of claim 11, wherein the computing device further comprises a second panel located on a second side of the heat generation module, mounted on the side walls, and provided with a plurality of heat dissipation grids, and the second side is opposite to the first side.

14. The computing device of claim 13, wherein the heat dissipation grids have a size in a range from 4.5 mm to 5.5 mm.

15. The computing device of claim 10, wherein a distance between the heat dissipation fan(s) in the heat dissipation apparatus and the heat generation module in a first direction ranges from 20 mm to 30 mm, and the first direction is a direction parallel to an air passage direction of the heat dissipation fan(s).

16. The computing device of claim 13, wherein a distance between the second panel and the heat generation module in a first direction ranges from 0 to 5 mm, and the first direction is a direction parallel to an air passage direction of the heat dissipation fan(s).

17. The computing device of claim 14, wherein the heat generation module comprises a plurality of computing power board assemblies arranged in parallel, a limiting body is disposed on a side of the second panel towards the heat generation module, and the limiting body abuts against at least one of the computing power board assemblies.

18. The computing device of claim 17, wherein the limiting body protrudes towards the heat generation module.

19. The computing device of claim 10, wherein the heat dissipation apparatus comprises two heat dissipation apparatuses located on two opposite sides of the heat generation module along a first direction respectively, and the first direction is a direction parallel to an air passage direction of the heat dissipation fans in the heat dissipation apparatuses.

20. The computing device of claim 10, wherein the heat generation module comprises a plurality of computing power board assemblies arranged in parallel, each disposed in the shell along a first direction, and the first direction is a direction parallel to an air passage direction of the heat dissipation fan(s) in the heat dissipation apparatus.

21. The computing device of claim 20, wherein a limiting strip is mounted on an inner side of a bottom wall and/or top wall of the side walls, the limiting strip is disposed along an arrangement direction of the computing power board assemblies, the limiting strip is located between the heat dissipation apparatus(es) and the computing power board assemblies, and each of the computing power board assemblies abuts against the limiting strip.
